(19) United States
(12) Patent Application Publication
(10) Pub. No.: US 2010/0133434 A1
(43) Pub. Date: Jun. 3, 2010

(54) Organic semiconductor infrared distance sensing apparatus and organic infrared emitting apparatus thereof

(75) Inventors: Hsin-Fei Meng, Hsinchu City (TW); Sheng-Fu Horng, Hsinchu City (TW); Hsin-Rong Tseng, Hsinchu City (TW); Chia-Ming Yang, Hsinchu City (TW); En-Chen Chen, Hsinchu City (TW)

Correspondence Address: OLIFF & BERRIDGE, PLC, P.O. BOX 320850, ALEXANDRIA, VA, 22320-4850, US

(73) Assignee: NATIONAL CHIAO TUNG UNIVERSITY, Hsinchu City (TW)

(21) Appl. No.: 12/385,356

(22) Filed: Apr. 6, 2009

(30) Foreign Application Priority Data
Nov. 28, 2008 (TW) 097146426

(51) Int. Cl. H01L 27/14

(52) U.S. Cl. 250/338.4

(57) ABSTRACT

An organic semiconductor infrared distance sensing apparatus and an organic infrared emitting apparatus thereof are disclosed. The organic semiconductor infrared distance sensing apparatus comprises an organic infrared emitting apparatus and an organic infrared receiving apparatus. The organic infrared emitting apparatus has a positive electrode layer and a negative electrode layer to form an electric field, and organic light emitting molecules are sandwiched between the two layers and correspond to the positive electrode layer and the negative electrode layer. Under a positive bias, a plurality of electrons and holes are respectively injected from electrodes and recombine with each other to emit photons. An infrared organic conversion layer absorbs and transfers the energy to infrared emitting molecules to emit infrared light. The organic infrared receiving apparatus receives the infrared light reflected by an obstacle to generate photocurrent which varies with distance, thereby sensing the distance between the obstacle and the apparatus.

### BACKGROUND OF THE INVENTION

(a) Field of the Invention

The present invention relates to an organic semiconductor infrared distance sensing apparatus and an organic infrared emitting apparatus thereof, and more particularly to a technical field of using completely organic materials as active layer devices which comprise light-emitting and detecting apparatuses, and sensing the distance between the obstacle and the apparatus by infrared light.

(b) Description of the Prior Art

In general, most polymers are insulators because their long hydrocarbon chains with covalent single bonds have no freely movable charges. However, conjugated conductive polymers are intrinsically conductive. Unlike conventional polymer composites doped with metal powders or conductive carbon blacks, conjugated conductive polymers are principally characterized in that the main chains of the polymers are composed of alternate conjugated single and double bonds and they have the ability to transport electrons and holes. Such polymers are totally referred to as conductive polymers. If electrons and holes can recombine with each other in organic polymers to emit photons, the polymers are referred to as organic light-emitting polymers. They can be made into organic light-emitting diodes and can be used in simple solution processes, such as spin coating, etc. This simplifies the problems of current complicant fabrication processes and expensive facilities for inorganic semiconductors.

Although organic semiconductors have the foregoing advantages and the like, their energy gaps mostly fall within the visible light range due to their energy band structures. Therefore, it is really hard to manufacture them into organic infrared emitting diodes or organic infrared receiving apparatuses. The present invention utilizes energy transfer to emit infrared light and utilizes an organic infrared receiver to receive the infrared light so as to determine the distance. This invention has never been disclosed in public before this patent application was filed.

To solve all the problems of the prior art, the inventors propose an organic semiconductor infrared distance sensing apparatus and an organic infrared emitting apparatus thereof based on their research and development for many years and plenty of practical experience, thereby improving the above defects.

### SUMMARY OF THE INVENTION

In view of the above-mentioned circumstances, an objective of the present invention is to provide an organic semiconductor infrared distance sensing apparatus for sensing an obstacle. The infrared distance sensing apparatus comprises an organic infrared emitting apparatus and an organic infrared receiving apparatus. The organic infrared emitting apparatus comprises an organic light-emitting diode and an infrared organic conversion layer. The infrared organic conversion layer comprises infrared dye molecules, and the infrared organic conversion layer absorbs and transfers the light emitted by the organic light-emitting diode to the infrared dye molecules to emit infrared light. The organic infrared receiving apparatus receives the infrared light reflected by an obstacle and generates an electrical signal corresponding to the infrared light. The electrical signal is associated with the distance between the obstacle and the infrared distance sensing apparatus.

Furthermore, another objective of the present invention is to provide an organic infrared emitting apparatus, which comprises an electrode layer having a positive electrode layer and a negative electrode layer to form an electric field and corresponding to each other; a light-emitting layer is located between the positive electrode layer and the negative electrode layer; and an infrared organic conversion layer is located at one side of the electrode layer, comprising energy conversion agent molecules and infrared dye molecules.

When the electrode layer is operated under a positive bias, a plurality of electrons and holes are respectively injected from the electrode layer into the light-emitting layer and recombine with each other in the light-emitting layer to emit photons. The infrared organic conversion layer absorbs and transfers the energy of the photons to the infrared emitting molecules to emit infrared light.

### BRIEF DESCRIPTION OF THE DRAWINGS

FIG. 1A is a schematic view of an embodiment of an organic infrared emitting apparatus according to the present invention;

FIG. 1B is a schematic view of another embodiment of an infrared organic conversion layer of an organic infrared emitting apparatus according to the present invention;

FIG. 2 is a schematic view showing a chemical structure of an energy conversion agent molecule of an organic infrared emitting apparatus according to the present invention;

FIG. 3 is a schematic view showing a chemical structure of an infrared dye molecule of an organic infrared emitting apparatus according to the present invention;

FIG. 4 is a schematic view of an embodiment of an organic semiconductor infrared distance sensing apparatus according to the present invention; and

FIG. 5 is a curve diagram of the correlation between the photocurrent signal strength and the distance according to the present invention.

### DETAILED DESCRIPTION OF THE PREFERRED EMBODIMENTS

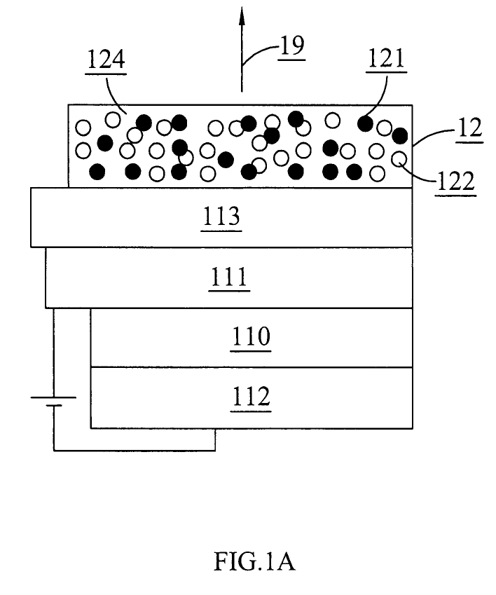

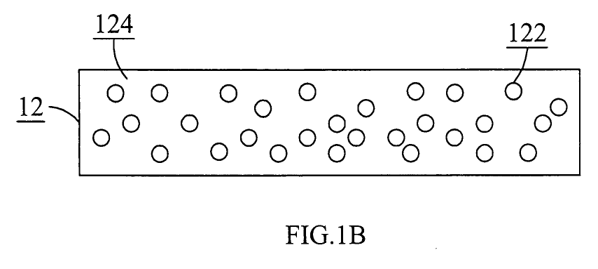

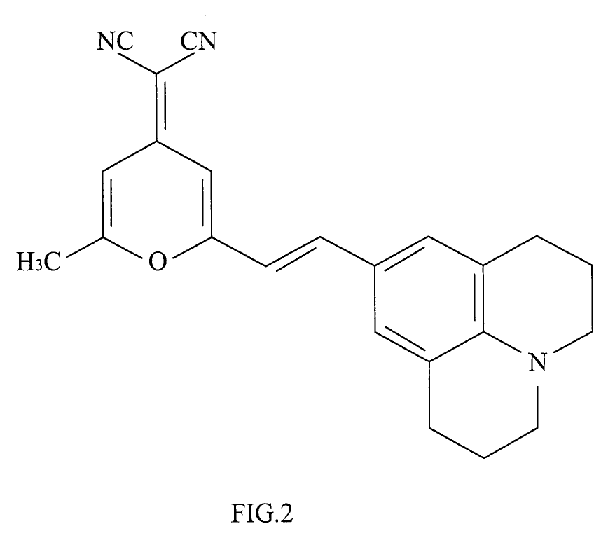

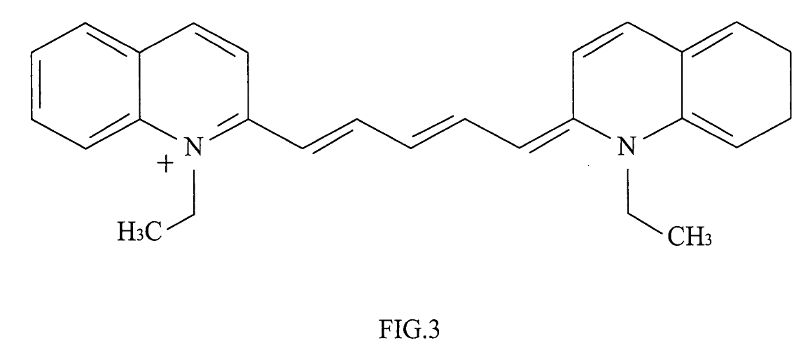

Referring to FIG. 1, illustrated is a schematic view of an embodiment of an organic infrared emitting apparatus according to the present invention. In this embodiment, the organic infrared emitting apparatus comprises an organic light-emitting diode and a conversion layer comprising energy conversion agent molecules and infrared dye molecules. The predetermined wavelength range of the light emitted by the organic light-emitting diode (OLED) is approximately the visible wavelength range from 400 nm to 700 nm. In this figure, the organic light-emitting diode has a positive electrode layer 111 and a negative electrode layer 112 to form an electric field, and the positive electrode layer 111 and the negative electrode layer 112 are corresponding to each other. When a positive bias is applied to between the positive electrode layer 111 and the negative electrode layer 112, holes and electrons are respectively injected from the positive electrode layer 111 and the negative electrode layer 112 into the light-emitting layer 110. A plurality of holes and a plurality of electrons recombine with each other in the light-emitting layer 110 to emit visible light, and are injected into an infrared organic conversion layer 12. The infrared organic conversion layer 12 is located on the glass 113 overlying the positive electrode layer 111. The infrared organic conversion layer 12 comprises an assistant film-forming host 124, energy conversion agent molecules 121 (DCM2) and infrared dye molecules 122. The energy conversion agent molecules 121 absorb the visible light emitted by the above organic light-emitting diode and transfer the energy of the visible light to the infrared dye molecules 122 to emit infrared light 19. The energy conversion agent molecules 121 are preferably of DCM2 (4-dicyanomethylene-2-methyl-6-(julolidin-4-yl-vinyl)-4H-pryan) represented by the chemical structural formula as shown in FIG. 2. The chemical structural formula of the preferable infrared dye molecules 122 is as shown in FIG. 3. Furthermore, it is hard to form a film from the energy conversion agent molecules 121 (DCM2) and the infrared dye molecules 122. Accordingly, in this embodiment, an assistant film-forming host 124, such as poly(vinylpyrrolidone) (PVP), poly(vinylcarbazole) (PVK), polymethylmethacrylate (PMMA) or polycarbonate (PC) assists in forming a film so as to form the infrared organic conversion layer 12.

Moreover, in another embodiment, there is another fabrication method for the infrared organic conversion layer 12. The infrared dye molecules 122 directly absorb the energy of the visible light emitted by the organic light-emitting diode such that the energy can be directly transferred to the infrared dye molecules 122. Due to the poor film-forming ability of the infrared dye molecules, an assistant film-forming host 124, such as PVP is used to assist in forming a film so as to form the infrared organic conversion layer 12, as shown in FIG. 1B.

The structure of an organic infrared sensing apparatus according to the present invention is similar to the above organic light-emitting diode. An active layer film is sandwiched between a cathode and an anode. This active layer film comprises two materials: one is an electron-donating material, P3HT, and the other is an electron-accepting material, PCBM. These two materials are mixed in equal proportions in the active layer film. When the infrared light is reflected into the active layer film, it is absorbed by the active layer film to generate excitons, i.e. electron and hole pairs. The excitons will be dissociated into electron carriers and hole carriers when they reaches the interface between P3HT and PCBM. This is because both electrons and holes would move toward lower energy levels. The HOMO energy of P3HT is lower relative to a hole; the LUMO energy of PCBM is lower relative to an electron. As a result, dissociated holes are conducted through P3HT and collected by the anode; electrons are conducted through PCBM and collected by the cathode. The current collected in a formed loop is photocurrent.

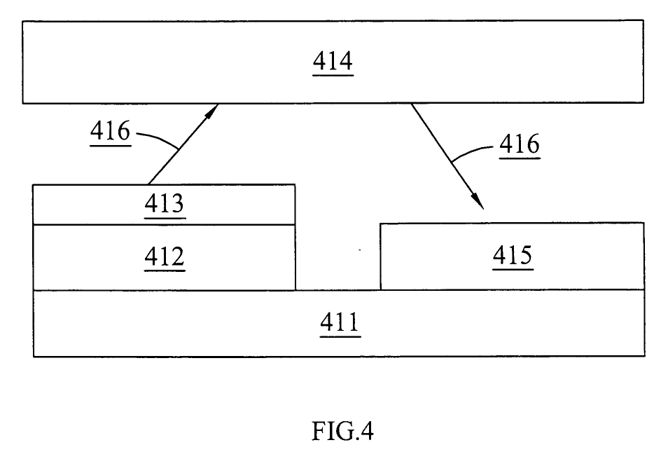

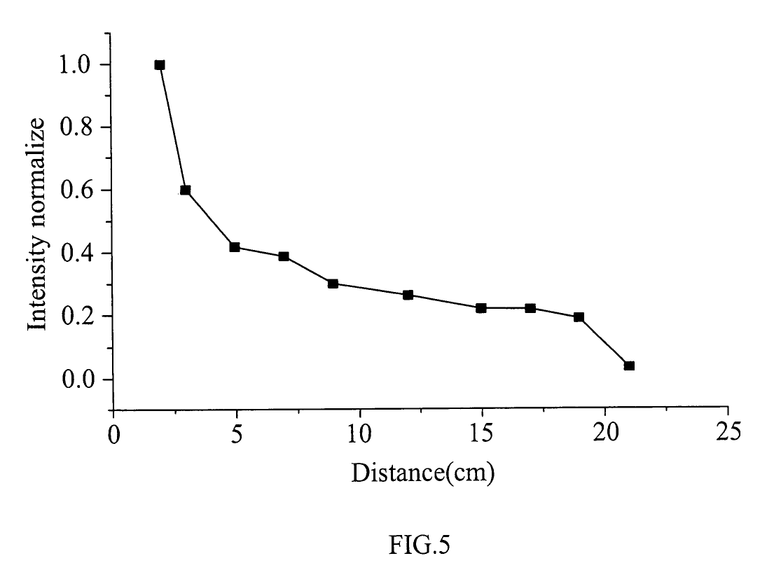

Referring to FIG. 4, illustrated is a schematic view of an embodiment of an organic semiconductor infrared distance sensing apparatus according to the present invention. In this figure, the infrared distance sensing apparatus is constructed on a substrate 411. An organic light-emitting diode 412 and an organic infrared receiving apparatus 415 are constructed on the same substrate 411, and an infrared organic conversion layer 413 is formed on the organic light-emitting diode 412. After the infrared organic conversion layer 413 absorbs the visible light from the organic light-emitting diode 412, absorber molecules absorb and transfer the energy to infrared dye molecules to emit infrared light 416. When the infrared light 416 strikes an obstacle 414, the infrared light 416 is reflected. The reflected infrared light 416 is received by the organic infrared receiving apparatus 415 and converted into an electrical signal, e.g. photocurrent. This electrical signal is associated with the distance between the obstacle 414 and the infrared distance sensing apparatus. Since the photocurrent value will change accordingly with changes in the distance between the obstacle 414 and the infrared distance sensing apparatus, the correlation between the photocurrent value generated by the infrared distance sensing apparatus and the distance can be measured previously, as shown in FIG. 5. Afterwards, the distance from a current obstacle 414 to the infrared distance sensing apparatus can be estimated according to the measured photocurrent value and the previously measured correlation above.

As mentioned above, the organic semiconductor infrared distance sensing apparatus according to the present invention has the following advantages:

(1) Completely organic materials are employed in the active layer of the organic infrared distance sensing apparatus. Thus, its process is simple, convenient and inexpensive, as well as it is suitable for use in a large area process and has flexibility.

(2) Light energy of a wavelength of a conventional visible light source can be absorbed by the organic infrared emitting apparatus whereby the convenience of the organic infrared emitting apparatus can be enhanced.

(3) Conventional dye molecules can be used as the absorbent material in the organic infrared emitting apparatus, thereby capable of improving the application of an organic semiconductor light-emitting apparatus to the control of color changing.

The above description is illustrative only and is not to be considered limiting. Various modifications or changes can be made without departing from the spirit and scope of the invention. All such equivalent modifications and changes shall be comprised within the scope of the appended claims.

What is claimed is:

1. An organic semiconductor infrared distance sensing apparatus for sensing an obstacle, the infrared distance sensing apparatus comprising:
an organic infrared emitting apparatus comprising an organic light-emitting diode and an infrared organic conversion layer, the infrared organic conversion layer comprising infrared dye molecules and the infrared organic conversion layer absorbing and transferring the light emitted by the organic light-emitting diode to the infrared dye molecules to emit infrared light; and
an organic infrared receiving apparatus that receives the infrared light reflected by the obstacle and generates an electrical signal corresponding to the infrared light;
wherein the electrical signal is associated with the distance between the obstacle and the infrared distance sensing apparatus.

2. The infrared distance sensing apparatus as claimed in claim 1, wherein the infrared organic conversion layer further comprises energy conversion agent molecules that receive the light emitted by the organic light-emitting diode and transfer energy of the light emitted by the organic light-emitting diode to the infrared dye molecules to emit the infrared light.

3. The infrared distance sensing apparatus as claimed in claim 1, wherein a predetermined wavelength range of the light emitted by the organic light-emitting diode is from 400 nm to 700 nm.

4. The infrared distance sensing apparatus as claimed in claim 1, wherein a positive electrode layer of the organic light-emitting diode is made of a high work function transparent conductive material.

5. The infrared distance sensing apparatus as claimed in claim 4, wherein the work function of the transparent conductive material is greater than 4.7 eV.

6. The infrared distance sensing apparatus as claimed in claim 4, wherein the positive electrode layer of the organic light-emitting diode is made of indium tin oxides (ITO), indium-zinc-oxide (IZO) or a high work function thin metal layer.

7. The infrared distance sensing apparatus as claimed in claim 6, wherein thickness of the thin metal layer is between 100 Å and 300 Å.

8. The infrared distance sensing apparatus as claimed in claim 1, wherein a negative electrode layer of the organic light-emitting diode is made of a low work function metal or composite layer of metal salt(s) and metal(s).

9. The infrared distance sensing apparatus as claimed in claim 8, wherein work function of the low work function metal is between 2 eV and 4.5 eV.

10. The infrared distance sensing apparatus as claimed in claim 8, wherein the metal salt is lithium fluoride (LiF) or cesium fluoride (CsF).

11. The infrared distance sensing apparatus as claimed in claim 1, wherein the organic light-emitting diode comprises a light-emitting layer and an electrode layer, and the infrared organic conversion layer is disposed at one side of the electrode layer, and while the electrode layer is operated under a positive bias, a plurality of electrons and holes are respectively injected from the electrode layer into the light-emitting layer and recombine with each other in the light-emitting layer to emit photons, and the infrared organic conversion layer absorbs and transfers the energy of the photons to the infrared dye molecules to emit the infrared light.

12. The infrared distance sensing apparatus as claimed in claim 11, wherein the infrared light has a wavelength range of from 700 nm to 1000 nm.

13. The infrared distance sensing apparatus as claimed in claim 1, wherein the infrared organic conversion layer further comprises an assistant film-forming host.

14. The infrared distance sensing apparatus as claimed in claim 11, wherein the infrared organic conversion layer comprises an assistant film-forming host.

15. The infrared distance sensing apparatus as claimed in claim 13 wherein the assistant film-forming host is poly(vinylpyrrolidone) (PVP), poly(vinylcarbazole) (PVK), polymethylmethacrylate (PMMA) or polycarbonate (PC).

16. The infrared distance sensing apparatus as claimed in claim 14, wherein the assistant film-forming host is poly(vinylpyrrolidone) (PVP), poly(vinylcarbazole) (PVK), polymethylmethacrylate (PMMA) or polycarbonate (PC).

17. The infrared distance sensing apparatus as claimed in claim 1, wherein the organic infrared receiving apparatus comprises:
an electrode layer having a positive electrode layer and a negative electrode layer to form an electric field; and
a photoelectric conversion layer located between the positive electrode layer and the negative electrode layer, receiving the infrared light to form electron and hole pairs and respectively forming a plurality of electrons and holes, the electric field driving the plurality of negative electrons to enable the electron and hole pairs to be adjacent respectively to the positive electrode layer and the negative electrode layer so as to generate the electrical signal corresponding to the infrared light.

18. The infrared distance sensing apparatus as claimed in claim 16, wherein the photoelectric conversion layer comprises a first predetermined material and a second predetermined material mixed in a predetermined ratio, and one of the first predetermined material and the second predetermined material is capable of absorbing radiation at infrared wavelengths by itself.

19. The infrared distance sensing apparatus as claimed in claim 16, wherein the photoelectric conversion layer comprises a first predetermined material and a second predetermined material mixed in a predetermined ratio, and the first predetermined material and the second predetermined material are not capable of absorbing radiation at infrared light wavelengths by themselves, and the interface of the first predetermined material and the second predetermined material receives the energy of a predetermined infrared wavelength domain.

20. The infrared distance sensing apparatus as claimed in claim 16, wherein the positive electrode layer is made of a high work function transparent conductive material.

21. The infrared distance sensing apparatus as claimed in claim 19, wherein work function of the transparent conductive material is greater than 4.7 eV.

22. The infrared distance sensing apparatus as claimed in claim 19, wherein the transparent conductive material is indium tin oxides (ITO), indium-zinc-oxide (IZO) or a high work function thin metal layer.

23. The infrared distance sensing apparatus as claimed in claim 16, wherein the negative electrode layer is made of a low work function metal.

24. The infrared distance sensing apparatus as claimed in claim 22, wherein work function of the metal is between 2 eV and 4.5 eV.
